(19) United States
(12) Patent Application Publication
(10) Pub. No.: US 2008/0131702 A1
(43) Pub. Date: Jun. 5, 2008

(54) Epoxy resin composition and semiconductor package including the same

(76) Inventors: Kyoung Chul Bae, Yongin-si (KR); Jin A. Kim, Seoul (KR); Yoon Kok Park, Suwon-si (KR)

Correspondence Address: LEE & MORSE, P.C., 3141 FAIRVIEW PARK DRIVE, SUITE 500, FALLS CHURCH, VA, 22042, US

(21) Appl. No.: 11/984,933

(22) Filed: Nov. 26, 2007

(30) Foreign Application Priority Data
Nov. 24, 2006 (KR) 10-2006-0117214

(51) Int. Cl. C08G 59/14; B32B 27/06; H01L 21/00

(52) U.S. Cl. 428/418; 524/500; 524/540; 438/127; 257/E21.001

(57) ABSTRACT

An epoxy resin composition includes an epoxy resin, a curing agent, a coupling agent, and an inorganic filler. The coupling agent may include a hydrocarbon-substituted siloxane resin having at least one terminal hydroxy group.

### BACKGROUND OF THE INVENTION

1. Field of the Invention

Embodiments relate to an epoxy resin composition and a semiconductor package including the same.

2. Description of the Related Art

With recent advances in the integration of semiconductor devices, remarkable progress has been made in the miniaturization of wires, the development of large-size devices and multilayer wiring. Packages may be formed to protect semiconductor devices from ambient conditions. Advances in manufacturing technologies have allowed such packages to be reduced in size and thickness, e.g., for high-density mounting such as surface mounting on printed boards.

Resin-encapsulated semiconductor devices, e.g., semiconductor devices encapsulated in small and thin packages, may suffer from frequent occurrences of defects such as package cracks and corrosion of aluminum pads due to thermal stresses resulting from changes in ambient conditions. One possible approach to solving the problem of package cracks is to increase the reliability of epoxy resin molding materials by, e.g., improving the adhesion of epoxy resin molding materials to metal features, reducing the modulus of elasticity of the epoxy resin molding materials to achieve low stress, or lowering the coefficient of thermal expansion of the epoxy resin molding materials. Other possible solutions include inhibiting the occurrence of corrosion though the use of high-purity epoxy resins or curing agents, reducing the occurrence of impurities through the use of ion trappers, and decreasing the amount of moisture absorbed through the use of larger amounts of inorganic fillers.

Semiconductor packages, e.g., packages wherein two or more chips are stacked in a vertical direction, have drawn a great deal of attention and interest in recent years as a way to manufacture high-performance electronic devices that are small and thin. Die attach films (DAFs) may be interposed between the chips in order to adhere the chips to each other. However, this stacking may be less reliable than a package wherein one chip is adhered to a metal pad by a metallic paste acting as a chip adhesive. For example, weak adhesion of the DAFs may cause delamination between the chips and the DAFs. Further, susceptibility of the DAFs to moisture may lead to a high possibility of package cracks. These problems have remained unsolved in the art.

### SUMMARY OF THE INVENTION

Embodiments are therefore directed to an epoxy resin composition and a semiconductor package including the same, which substantially overcome one or more of the problems due to the limitations and disadvantages of the related art.

It is therefore a feature of an embodiment to provide an epoxy resin composition that includes a hydrocarbon-substituted siloxane resin having at least one terminal hydroxy group as a coupling agent.

It is therefore another feature of an embodiment to provide a semiconductor package including a chip and a polymeric epoxy encapsulation, and a method of packaging a chip.

At least one of the above and other features and advantages may be realized by providing an epoxy resin composition, including an epoxy resin, a curing agent, a curing accelerator, a coupling agent, and an inorganic filler. The coupling agent may include a hydrocarbon-substituted siloxane resin having at least one terminal hydroxy group.

The hydrocarbon substituents of the siloxane resin may each be independently a C₁-C₆ alkyl or phenyl group. At least some of the hydrocarbon substituents may be methyl groups.

The siloxane resin may be a silsesquioxane having a ladder structure with four terminal hydroxy groups. The siloxane resin may be a methyl/phenylsilsesquioxane resin. The siloxane resin may have a structure represented by Structure 1:

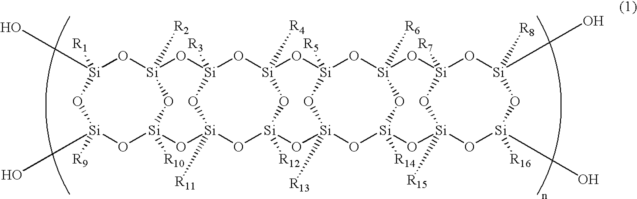

In Structure 1, n may be from 1 to about 20, and R₁ to R₁₆ may be the hydrocarbon substituents. R₁ to R₁₆ may each be methyl. R₁ to R₁₆ may each be phenyl.

The siloxane resin may be in a liquid state at room temperature. The siloxane resin may have a viscosity in a 40% butanol solution at room temperature of about 200 to about 800 cps. The siloxane resin may have a specific gravity of about 1 to about 1.6. The siloxane resin may have a refractive index of about 1.4 to about 1.6.

About 0.01% to about 10% of the weight of the composition may be the coupling agent. About 20% or more of the weight of the coupling agent may be the siloxane resin.

The epoxy resin may include a biphenyl type epoxy resin represented by Structure 2 in FIG. 4A. In Structure 2, n may be an average of 1 to about 7.

The curing agent may include a phenol aralkyl-type phenolic resin represented by Structure 4:

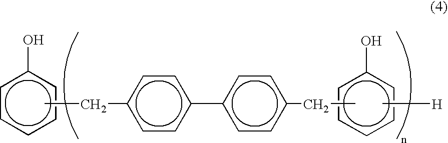

In Structure 4, n may be an average of 1 to about 7.

At least one of the above and other features and advantages may also be realized by providing a semiconductor package, including at least one chip, and a polymeric epoxy encapsulation that includes an epoxy resin component, a curing agent component, a curing accelerator component, a coupling agent component, and an inorganic filler component. The coupling agent component may include a hydrocarbon-substituted siloxane resin having at least one terminal hydroxy group.

The chip may include a metal feature containing a significant portion of one or more of silver, copper, nickel, gold, or platinum, and the polymeric epoxy encapsulation may be in direct contact with the metal feature.

At least one of the above and other features and advantages may also be realized by providing a method of packaging a chip, including providing at least one chip, providing an epoxy resin composition that includes an epoxy resin, a curing agent, a curing accelerator, a coupling agent, and an inorganic filler, wherein the coupling agent may include a hydrocarbon-substituted siloxane resin having at least one terminal hydroxy group, and forming an epoxy encapsulation around the chip using the composition.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIG. 1 illustrates Table 1, listing components used in Examples 1 and 2 and in Comparative Examples 1-3;

FIG. 2 illustrates Table 2, listing physical properties of epoxy resin compositions prepared according to Examples 1 and 2 and according to Comparative Examples 1-3;

FIG. 3 illustrates an example semiconductor package according to an embodiment; and

FIGS. 4A-4C illustrate Structures 1-5.

### DETAILED DESCRIPTION OF THE INVENTION

Korean Patent Application No. 10-2006-0117214, filed on Nov. 24, 2006, in the Korean Intellectual Property Office, and entitled: “Epoxy Resin Composition for Encapsulating Multichip Package and Multichip Package Using the Same,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art. In the figures, the dimensions of layers and regions may be exaggerated for clarity of illustration. Like reference numerals refer to like elements throughout.

As used herein, the expressions “at least one,” “one or more,” and “and/or” are open-ended expressions that are both conjunctive and disjunctive in operation. For example, each of the expressions “at least one of A, B, and C,” “at least one of A, B, or C,” “one or more of A, B, and C,” “one or more of A, B, or C” and “A, B, and/or C” includes the following meanings: A alone; B alone; C alone; both A and B together; both A and C together; both B and C together; and all three of A, B, and C together. Further, these expressions are open-ended, unless expressly designated to the contrary by their combination with the term “consisting of.” For example, the expression “at least one of A, B, and C” may also include an n^{th} member, where n is greater than 3, whereas the expression “at least one selected from the group consisting of A, B, and C” does not.

As used herein, the expression “or” is not an “exclusive or” unless it is used in conjunction with the term “either.” For example, the expression “A, B, or C” includes A alone; B alone; C alone; both A and B together; both A and C together; both B and C together; and all three of A, B and, C together, whereas the expression “either A, B, or C” means one of A alone, B alone, and C alone, and does not mean any of both A and B together; both A and C together; both B and C together; and all three of A, B and C together.

Example embodiments will now be described in greater detail. Embodiments may provide an epoxy resin composition suitable for forming the encapsulation of a semiconductor package, and a chip package formed using the epoxy resin composition. The epoxy resin composition may exhibit enhanced adhesion to metal features, enhanced moisture resistance, crack resistance at high temperatures, and other mechanical properties that are desirable to provide high reliability and improved molding properties.

The present invention provides an epoxy resin composition for the encapsulation of a semiconductor package, including an epoxy resin, a curing agent, a coupling agent, and an inorganic filler. In an implementation, the epoxy resin composition may include a curing accelerator. The epoxy resin may be a single resin or a mixture of resins, the curing agent may be a single curing agent or a mixture of curing agents, the coupling agent may be a single agent or a mixture of agents, the inorganic filler may be a single filler or a mixture of fillers, and the curing accelerator may be a single accelerator or a mixture of accelerators.

The coupling agent may include a hydrocarbon-substituted siloxane resin having at least one hydroxy group, e.g., a terminal hydroxy group. Preferably, the siloxane resin is a high-purity methylsiloxane resin such as methylsilsesquioxane or a high-purity phenylsiloxane resin such as phenylsilsesquioxane. Preferably, the siloxane resin has a refractive index of about 1.4 to about 1.6. For example, when only methylsilsequioxane is used, the refractive index may be about 1.4, and when only phenylsilsesquioxane is used, the refractive index may be about 1.6. The siloxane resin is preferably in a liquid state at room temperature, which may help ensure that the siloxane resin is well dispersed.

In an implementation, the siloxane resin may have a ladder structure as represented by Structure 1:

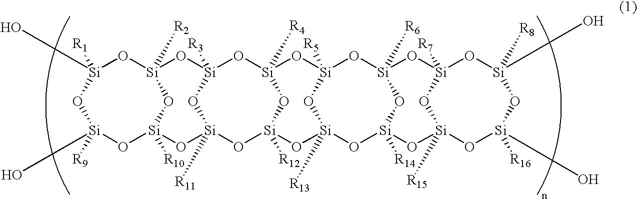

In Structure 1, n may be from 1 to about 20, which may impart the desired levels of adhesiveness and viscosity. If n is greater than about 20, flowability may decrease due to an increase in viscosity. The hydrocarbon substituents R₁ to R₁₆ may be independently a C₁-C₆ alkyl group or an aryl group such as phenyl. Such a siloxane resin may be obtained commercially from, e.g., Techneglas Co., Ltd. (United States). The ladder structure may be more advantageous than linear structures and network structures in terms of reliability of a semiconductor package encapsulated with the epoxy resin composition.

Preferably, the resin of Structure 1 has a specific gravity of about 1 to about 1.6 and a viscosity in a 40% butanol solution at room temperature of about 200 to about 800 cps.

In Structure 1, the hydrocarbon substituents R₁ to R₁₆ are preferably methyl groups.

The siloxane resin may be an oligomeric adhesion promoter, and may serve to improve the adhesion to metal features, as well as improve moisture resistance and toughness of the epoxy resin composition. The siloxane resin may impart the epoxy resin composition with significantly greater adhesion to metal features, e.g., those that include significant or substantial portions of copper, nickel alloys such as Alloy 42, silver, which is used as a plating metal on main parts of semiconductor packages but has a weak adhesive force, and gold and platinum, which are main constituent metals for pre-plated frames (PPFs) used for environmentally friendly lead frame materials. The epoxy resin composition may also provide enhanced adhesiveness after post-curing, as well as reduced moisture absorption. The epoxy resin composition may also provide high reliability and improved moldability in the encapsulation of a semiconductor package adhered by die attach films (DAFs), due to the adhesiveness, moisture resistance and toughness provided by the epoxy resin composition.

Preferably, about 0.01% to about 10% of the total weight of the epoxy resin composition is the coupling agent. The siloxane resin may be used alone or in combination with another coupling agent. When used in combination with another coupling agent, the siloxane resin is preferably more than about 20% of the total weight of all coupling agents used.

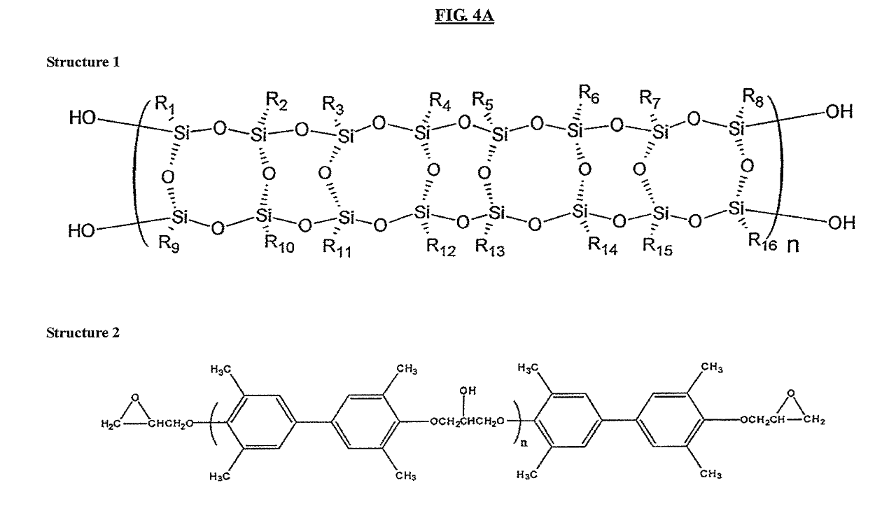

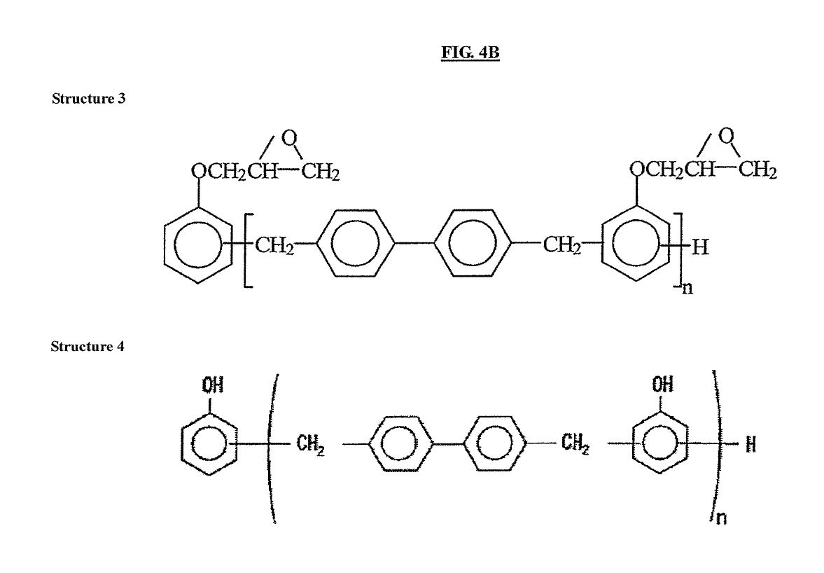

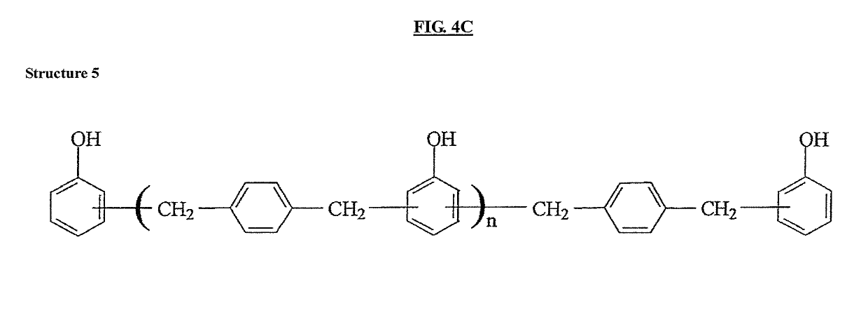

Examples of suitable epoxy resins in the epoxy resin composition include cresol novolac-type epoxy resins, phenol novolac-type epoxy resins, biphenyl-type epoxy resins, bisphenol A-type epoxy resins, bisphenol F-type epoxy resins, linear aliphatic epoxy resins, alicyclic epoxy resins, heterocyclic epoxy resins, epoxy resins having one or more spiro rings, xylok-type epoxy resins, phenol aralkyl-type epoxy resins, each of which may be used alone or in combination with one or more other epoxy resins. Biphenyl-type and phenol aralkyl-type epoxy resins are preferred as the epoxy resins, and are respectively represented by Structure 2 as shown in FIG. 4A and Structure 3 below:

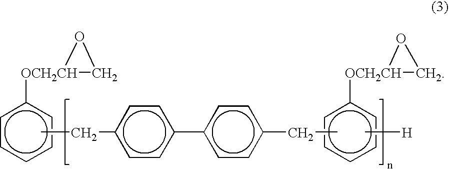

In Structure 2, n may be an average of about 1 to about 7. In Structure 3, n may be an average of about 1 to about 7 and may be different from Structure 2.

When a combination of epoxy resins is used, the biphenyl-type epoxy resin of Structure 2 is preferably used in an amount of about 40% or more, and more particularly about 70% or more, of the combined weight of the epoxy resins. The use of the biphenyl-type epoxy resin may impart desirable properties to the epoxy resin composition. An adduct, i.e., a partial reaction product, of the biphenyl-type epoxy resin may be used. Preferably, about 3% to about 15% and, more preferably, about 3% to about 12%, of the total weight of the epoxy resin composition is the epoxy resin.

The curing agents used in the epoxy resin composition may be materials that can react with the epoxy resins to form cured products. Specific examples of such curing agents include various novolac-type resins synthesized from phenol novolac resins, cresol novolac resins, bisphenol A and resol. Other examples include polyhydric phenolic compounds such as tris(hydroxyphenyl)methane and dihydroxybiphenyl. Other examples include acid anhydrides such as maleic anhydride and phthalic anhydride. Other examples include aromatic amines such as m-phenylenediamine, diaminodiphenylmethane and diaminodiphenylsulfone. Phenolic curing agents may be used for semiconductor molding applications, due to the heat resistance, moisture resistance and storage stability provided by these compounds. In some implementations, it may be desirable to use two types of curing agents, depending on the intended application.

Phenol aralkyl-type and xylok-type phenolic resins are preferred as curing agents, and are represented by the following Structures 4 and 5, respectively:

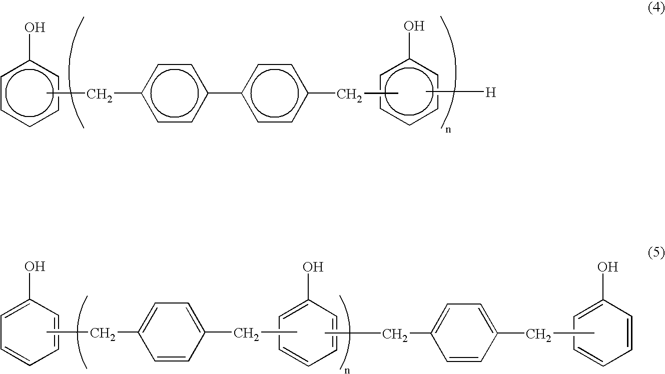

In Structure 4, n may be an average of about 1 to about 7. In Structure 5, n may be an average of about 1 to about 7. In each of Structures 2-5, n may be different.

Where a combination of phenolic resins is used, the phenol aralkyl-type phenolic resin may be about 20% or more, e.g., about 30% or more, of the total weight of the combined phenolic resins. Preferably, about 0.1% to about 10%, more preferably about 0.5% to about 7%, of the total weight of the epoxy resin composition is the curing agent. The chemical equivalent ratio of curing agent:epoxy resin is preferably about 0.5:1 to about 1.5:1 and, more preferably, about 0.8:1 to about 1.2:1.

The curing accelerator used in the present invention serves to promote the reaction between the epoxy resins and the curing agents. Preferably, about 0.1% to about 10% of the total weight of the epoxy resin composition is the curing accelerator.

Examples of suitable curing accelerators include tertiary amines, organometallic compounds, organic phosphorus compounds, imidazoles and boron compounds. Examples of suitable tertiary amines include benzyldimethylamine, 2-2-(dimethylaminomethyl)phenol, 2,4,6-tris(diaminomethyl)phenol and salts of tri-2-ethylhexanoic acid. Examples of suitable organometallic compounds include chromium acetylacetonate, zinc acetylacetonate, and nickel acetylacetonate. Examples of suitable organic phosphorus compounds include tris-4-methoxyphosphine, tetrabutylphosphonium bromide, butyltriphenylphosphonium bromide, triphenylphosphine, tliphenylphosphine triphenylborane, and triphenylphosphine-1,4-benzoquinone adducts. Examples of suitable imidazoles include 2-methylimidazole, 2-aminoimidazole, 2-methyl-1-vinylimidazole, 2-ethyl-4-methylimidazole, and 2-heptadecylimidazole. Examples of suitable boron compounds include trifluoroborane-n-hexylamine, trifluoroborane monoethylamine, tetrafluoroborane triethylamine, and tetrafluoroborane amine. In addition to these compounds, 1,8-diazabicyclo[5.4.0]undec-7-ene (DBU) salts and phenol novolac resin salts may be used.

The inorganic filler used in the epoxy resin composition may impart improved mechanical properties and lower stress. The amount of inorganic filler used in the epoxy resin composition may be varied according to the physical properties desired, in order to control such factors as moldability, stress and high-temperature strength of the epoxy resin composition. Preferably, about 70% to about 95% and, more preferably, about 80% to about 95% of the total weight of the epoxy resin composition is the inorganic filler.

Suitable fillers include fused silica, crystalline silica, calcium carbonate, magnesium carbonate, alumina, magnesia, clay, talc, calcium silicate, titanium oxide, antimony oxide, and glass fibers. Fused silica having a low linear coefficient of thermal expansion is preferably used to achieve low stress. The fused silica may be amorphous silica having a true specific gravity of about 2.3 or less. The amorphous silica may be prepared by melting crystalline silica, or may be synthesized from various raw materials. The shape and particle diameter of the fused silica may be varied according to the application.

About 50% to about 99% of the total weight of the filler may be spherical fused silica having an average particle diameter of about 5 μm to about 30 μm, and about 1% to about 50% of the total weight of the filler may be spherical fused silica having an average particle diameter of 1 μm or less. In another implementation, about 40% or more and, more particularly, 60% or more of the total weight of the filler may be silica.

Depending on the application, the epoxy resin composition may further include one or more additives, e.g., release agents such as higher fatty acids, higher fatty acid metal salts and ester type waxes, colorants such as carbon black, organic dyes and inorganic dyes, other coupling agents such as epoxy silane, aminosilane, mercaptosilane and alkylsilane, and/or stress relaxing agents such as modified silicone oils, silicone powders and silicone resins.

About 0.1% to about 6.5% of the total weight of the epoxy resin composition may be the stress relaxing agent. When implemented, the modified silicone oils and silicone powders used as stress relaxing agents may be used alone or in combination.

Highly heat-resistant silicone polymers are a preferred example of the modified silicone oil. The modified silicone oil(s) may include silicone oils having an epoxy group, silicone oils having an amine group, and/or silicone oils having a carboxyl group. About 0.05% to about 1.5% of the total weight of the epoxy resin composition may be the silicone oils. Using less than about 1.5% may help reduce or eliminate surface contamination, and may shorten or eliminate resin bleed. Using more than about 0.05% may impart a desirably low modulus of elasticity.

The silicone powders preferably have a mean particle diameter of about 15 μm or less, as such a size may avoid undue reductions in moldability. Preferably, when silicone powder is used, about 0.05% to about 5% of the weight of the epoxy resin composition is silicone powder.

The epoxy resin composition may be prepared using generally known processes. For example, predetermined amounts of the respective components may first be homogeneously and sufficiently mixed using a Henschel or Lodige mixer. Thereafter, the mixture may be melt-kneaded using a roll mill or a kneader, cooled, and pulverized to obtain a powder. Processes such as low-pressure transfer molding, injection molding or casting may be employed to produce a semiconductor package using the powder.

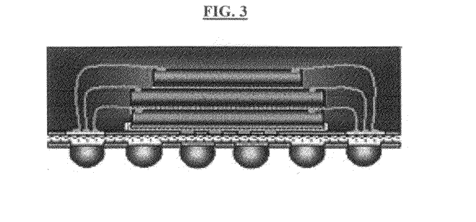

The epoxy resin composition may be used to form a semiconductor package in which a chip is encapsulated with an epoxy to provide protection from the surrounding environment, e.g., as shown in FIG. 3. The chip package may include a chip or a plurality of chips. The package may contain an optical chip, a MEMS chip, etc., instead of or in addition to a semiconductor ship. The chip or chips may be surrounded by a polymeric encapsulation that includes an epoxy resin component, a curing agent component, a coupling agent component, and an inorganic filler component. The coupling agent component may include a hydrocarbon-substituted siloxane resin having at least one terminal hydroxy group, e.g., a compound represented by Structure 1. The chip or chips may include a silver or copper-containing metal features, and the epoxy encapsulation may be in direct contact with the metal features. Notably, the epoxy resin composition according to embodiments may provide enhanced adhesiveness to such metal features.

### EXAMPLES

The following Examples and Comparative Examples are provided in order to set forth particular details of one or more embodiments. However, it will be understood that the embodiments are not limited to the particular details described.

### Examples 1 and 2, and Comparative Examples 1-3

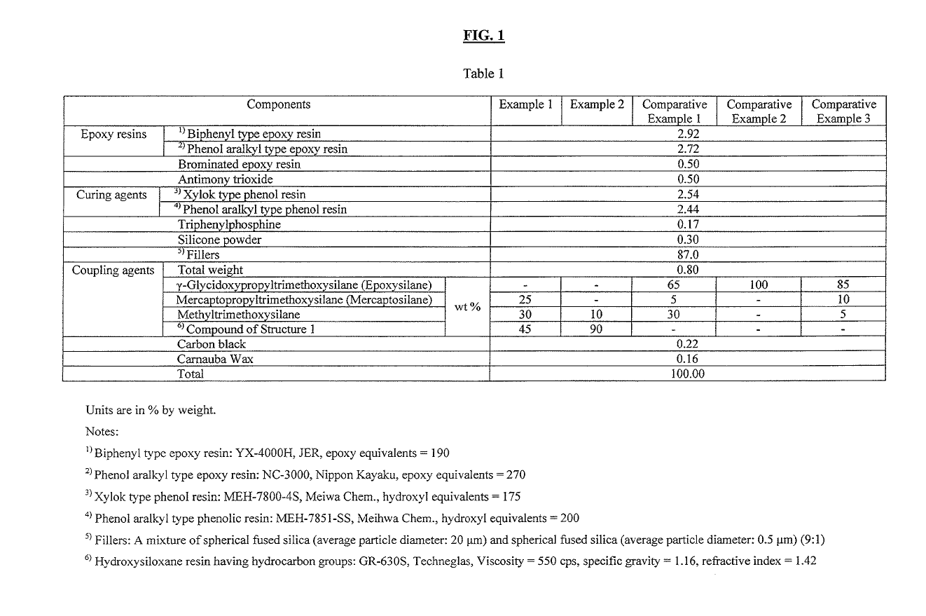

In accordance with the compositions shown in FIG. 1, Table 1, the respective components of the Examples and Comparative Examples were homogeneously mixed using a Henschel mixer, melt-kneaded at 100° C. to 120° C. using a continuous kneader, cooled, and pulverized to prepare epoxy resin compositions for semiconductor molding.

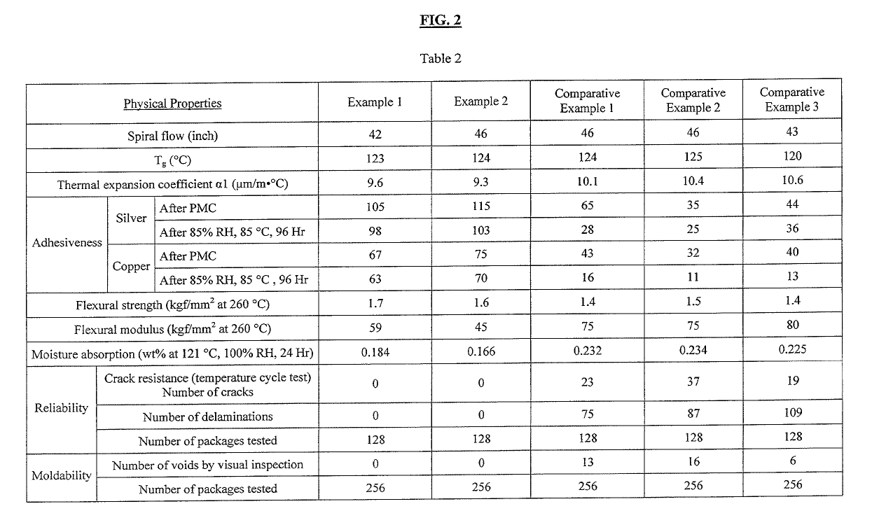

The physical properties of the epoxy resin compositions were evaluated by the following respective methods. The results are shown in FIG. 2, Table 2.

### Evaluation Methods of Physical Properties

The spiral flow of the compositions, a test of flowability, was measured using a transfer molding press in a mold for evaluation at 175° C., in accordance with procedure EMMI 1-66.

The glass transition temperature (Tg) of the compositions was measured using a thermomechanical analyzer (TMA).

The thermal expansion coefficient (al) of the compositions was evaluated in accordance with procedure ASTM D-696.

The flexural strength and flexural modulus of the compositions were measured in accordance with procedure ASTM D-790. First, each of the compositions was produced as a standard specimen, which was cured at 175° C. for 4 hours to obtain a test specimen. A universal testing machine (UTM) was used to measure the flexural strength and flexural modulus of the test specimens.

The crack resistance of the compositions, a test of reliability, was evaluated by counting the number of cracks formed after 1,000 cycles in a temperature cycle tester following preconditioning, as observed using a scanning acoustic tomograph (SAT), which is a nondestructive detector.

### a) Preconditioning

Each of the epoxy resin compositions was used to produce a multichip package. The multichip package was dried at 125° C. for 24 hours, subjected to five cycles of a temperature cycle test, allowed to stand at 850° C. and a relative humidity of 85% for 96 hours, and passed through an IR reflow at 260° C. three times on a 10 second cycle. Thereafter, the packages were observed to determine whether cracks were formed in the multichip packages. If cracks were formed, the subsequent step, i.e., 1,000 cycles of a temperature cycle test, was not conducted.

### b) Temperature Cycle Test

The multichip packages having undergone the preconditioning conditions were left to stand at −65° C. for 10 minutes, 25° C. for 5 minutes and 150° C. for 10 minutes (one cycle). After the cycle was repeated 1,000 times, the existence of internal and external cracks was observed using a nondestructive detector (SAT).

### c) Reliability Test

The compositions were molded at 175° C. for 70 seconds using a multi-plunger system (MPS) and post-cured at 175° C. for 2 hours to produce multichip packages, each of which was composed of four semiconductor chips stacked in a vertical direction using DAFs. The reliability of the compositions was evaluated by counting the number of cracks in the corresponding multichip packages after the temperature cycle test.

The physical properties, moldability, flexural properties and reliability of the epoxy resin compositions are shown in Table 2. The results shown in Table 2 demonstrate that the epoxy resin compositions prepared in Examples 1 and 2 showed good adhesion to the metals, high reliability and improved moldability when compared to the epoxy resin compositions prepared in Comparative Examples 1-3. Further, with respect to moisture absorption, better results were obtained in the epoxy resin compositions prepared in Examples 1 and 2, indicating excellent moisture resistance.

As described above, an epoxy resin composition according to embodiments may include a hydrocarbon-substituted siloxane resin having at least one hydroxy group as a coupling agent, and may be used to produce a package with improved moisture resistance, crack resistance and toughness. In addition, the epoxy resin composition of the present invention may inhibit the formation of voids during molding of a package, which may provide excellent molding properties and result in a package having high reliability.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. An epoxy resin composition, comprising:
an epoxy resin;
a curing agent;
a curing accelerator;
a coupling agent; and
an inorganic filler, wherein the coupling agent includes a hydrocarbon-substituted siloxane resin having at least one terminal hydroxy group.

2. The epoxy resin composition as claimed in claim 1, wherein the hydrocarbon substituents of the siloxane resin are each independently a C₁-C₆ alkyl or phenyl group.

3. The epoxy resin composition as claimed in claim 2, wherein at least some of the hydrocarbon substituents are methyl groups.

4. The epoxy resin composition as claimed in claim 1, wherein the siloxane resin is a silsesquioxane having a ladder structure with four terminal hydroxy groups.

5. The epoxy resin composition as claimed in claim 4, wherein the siloxane resin is a methyl/phenylsilsesquioxane resin.

6. The epoxy resin composition as claimed in claim 4, wherein the siloxane resin has a structure represented by Structure 1: 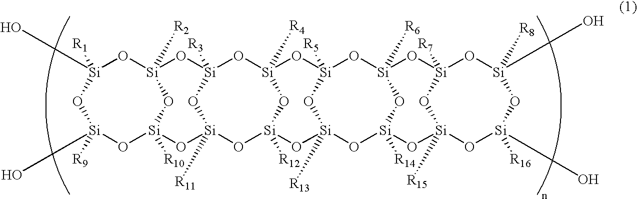
wherein n is from 1 to about 20, and R₁ to R₁₆ are the hydrocarbon substituents.

7. The epoxy resin composition as claimed in claim 6, wherein R₁ to R₁₆ are each methyl.

8. The epoxy resin composition as claimed in claim 6, wherein R₁ to R₁₆ are each phenyl.

9. The epoxy resin composition as claimed in claim 1, wherein the siloxane resin is in a liquid state at room temperature.

10. The epoxy resin composition as claimed in claim 9, wherein the siloxane resin has a viscosity in a 400% butanol solution at room temperature of about 200 to about 800 cps.

11. The epoxy resin composition as claimed in claim 1, wherein the siloxane resin has a specific gravity of about 1 to about 1.6.

12. The epoxy resin composition as claimed in claim 1, wherein the siloxane resin has a refractive index of about 1.4 to about 1.6.

13. The epoxy resin composition as claimed in claim 1, wherein about 0.01% to about 10% of the weight of the composition is the coupling agent.

14. The epoxy resin composition as claimed in claim 13, wherein about 20% or more of the weight of the coupling agent is the siloxane resin.

15. The epoxy resin composition as claimed in claim 1, wherein the epoxy resin includes a biphenyl type epoxy resin represented by Structure 2: 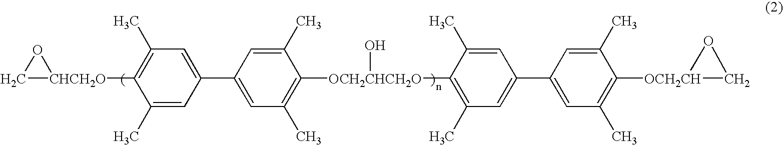
wherein n is an average of 1 to about 7.

16. The epoxy resin composition as claimed in claim 15, wherein the curing agent includes a phenol aralkyl-type phenolic resin represented by Structure 4: 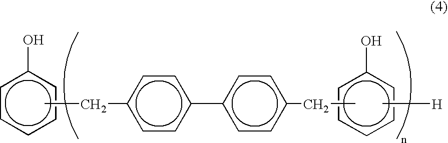
wherein n is an average of 1 to about 7.

17. A chip package, comprising:
at least one chip, and
a polymeric epoxy encapsulation that includes:
an epoxy resin component;
a curing agent component;
a curing accelerator component;
a coupling agent component; and
an inorganic filler component, wherein the coupling agent component includes a hydrocarbon-substituted siloxane resin having at least one terminal hydroxy group.

18. The chip package as claimed in claim 18, wherein:
the chip includes a metal feature containing a significant portion of one or more of silver, copper, nickel, gold, or platinum, and
the polymeric epoxy encapsulation is in direct contact with the metal feature.

19. A method of packaging a chip, comprising:
providing at least one chip;
providing an epoxy resin composition that includes:
an epoxy resin;
a curing agent;
a curing accelerator;
a coupling agent; and
an inorganic filler, wherein the coupling agent includes a hydrocarbon-substituted siloxane resin having at least one terminal hydroxy group; and
forming an epoxy encapsulation around the chip using the composition.
